(19) United States
(12) Patent Application Publication
(10) Pub. No.: US 2024/0138246 A1
(43) Pub. Date: Apr. 25, 2024

(54) PREPARATION METHOD AND PHOTOELECTRIC DEVICE OF TIN-BASED PEROVSKITE THIN FILM EMPLOYING STRESS CONTROL

(71) Applicant: Huazhong University of Science and Technology, Wuhan, Hubei (CN)

(72) Inventors: Mingkui WANG, Wuhan, Hubei (CN); Haixuan YU, Wuhan, Hubei (CN); Xiongjie LI, Wuhan, Hubei (CN); Zhiguo ZHANG, Wuhan, Hubei (CN)

(21) Appl. No.: 18/554,540

(22) PCT Filed: Nov. 23, 2022
(86) PCT No.: PCT/CN2022/133587

§ 371 Date: Oct. 8, 2023

(30) Foreign Application Priority Data
Oct. 20, 2022 (CN) 202211294766.6

(51) Int. Cl. H10K 71/16; H10K 30/50; H10K 85/50

(52) U.S. Cl. CPC H10K 71/164; H10K 30/50; H10K 85/50

(57) ABSTRACT

A tin-based perovskite thin film employing stress control, a preparation method therefor, and a photoelectric device are provided. The preparation method includes placing a tin-based perovskite solution film and a ligand solution in the same chamber, making a degree of vacuum of the chamber lower than 1,000 Pa by performing air pumping, and then stopping air pumping, wherein the ligand solution is a solution containing an amino or mercapto functional group; maintaining the chamber to be in a closed state, so that tin-based perovskite is complexed with a solvent to form a mesophase solid film with an ability to resist thermal stress impact, the ligand solution continues to be volatilized to fill the chamber to form a ligand atmosphere, and the ligand is combined with the uncoordinated tin ion in the mesophase solid film to reduce surface defects; and taking out the mesophase solid film and annealing.

### TECHNICAL FIELD

The present invention relates to the field of photoelectric technology, and more specifically relates to a preparation method and a photoelectric device of a tin-based perovskite thin film employing stress control.

### BACKGROUND ART

Compared with conventional lead-based perovskite, tin-based perovskite has excellent photoelectric properties such as a narrow optical band gap and better light and thermal stability, and is the most promising perovskite material for achieving high efficiency, stability and low toxicity. Obtaining a uniform, dense and high-quality perovskite thin film is the key to the preparation of high-performance perovskite photoelectric devices. However, perovskite is more susceptible to lattice distortion caused by external light and heat due to its low Young's modulus. Moreover, there is an annealing step in the preparation process of perovskite thin films. The annealing process may lead to lattice tensile strain to distort the lattice, and the distorted region becomes a defect center, which enhances the non-radiative recombination of carriers, resulting in the degradation of the performance of tin-based perovskite photoelectric devices. Therefore, it is desirable to seek a process method to reduce tin-based perovskite defects, which is of great significance to improve the photoelectric performance of the device.

### SUMMARY OF THE INVENTION

In view of the above defects or improvement needs of the prior art, the present invention provides a tin-based perovskite thin film employing stress control, a preparation method therefor, and a photoelectric device, which aim to solve the technical problem that tin-based perovskite has many defects.

In order to achieve the above objective, according to one aspect of the present invention, a method for preparing a tin-based perovskite thin film employing stress control is provided. The method comprises:
applying a tin-based perovskite solution to a surface of a substrate to form a tin-based perovskite solution film;
placing the tin-based perovskite solution film and a ligand solution in the same chamber, making a degree of vacuum of the chamber lower than 1,000 Pa by performing air pumping, and then stopping air pumping, wherein the ligand solution is a solution containing an amino or mercapto functional group;
maintaining the chamber to be in a closed state, so that part of a solvent in the tin-based perovskite solution film is volatilized, tin-based perovskite is complexed with the solvent to form a mesophase solid film with an ability to resist thermal stress impact, the ligand solution continues to be volatilized to fill the chamber to form a ligand atmosphere, and the volatilized ligand is combined with uncoordinated tin in the intermediate solid phase film to reduce surface defects; and
taking out the intermediate solid phase film and annealing at a temperature of 45° C. to 110° C.

In one embodiment, the volume of the ligand solution is 10 μL to 50 μL, the degree of vacuum is 100 Pa to 1,000 Pa, and a duration of maintaining the chamber in the closed state is 60 s to 180 s.

In one embodiment, a duration of performing air pumping to make the degree of vacuum of the chamber lower than 1,000 Pa is not more than 10 s.

In one embodiment, a duration of low-temperature annealing is 3 min to 5 min, and a duration of high-temperature annealing is 5 min to 15 min.

In one embodiment, during annealing, low-temperature annealing at 45° C. to 50° C. is performed first, and then high-temperature annealing at 90° C. to 110° C. is performed.

In one embodiment, the ligand solution is a mixture of any one or more of methylamine, dimethylamine, ethylamine, diethylamine, ethylenediamine, dipropylamine, 2-phenylethanethiol, ethanethiol, and ethane-1,2-dithiolphenol.

In one embodiment, the solvent in the tin-based perovskite solution is formed by mixing any one or more of dimethylformamide, dimethylsulfoxide, N,N-dimethylacetamide, y-butyrolactone, and N-methylpyrrolidone.

In one embodiment, a solute in the tin-based perovskite solution consists of one or more of methylamine tin iodide, formamidinium tin iodide, methylamine tin iodide bromide, formamidinium tin iodide bromide, cesium tin iodide, cesium tin iodide bromide, phenethylamine tin iodide, n-butylamine tin iodide, isobutylamine tin iodide or xylylenediamine tin iodide.

According to another aspect of the present invention, a tin-based perovskite thin film is provided. The tin-based perovskite thin film is prepared by any one of the above methods for preparing the tin-based perovskite thin film employing stress control.

According to still another aspect of the present invention, a photoelectric device comprising the above tin-based perovskite thin film is provided.

In general, compared with the prior art, the technical solutions above of the present inventive concept can achieve the following beneficial effects:

In the present invention, after the perovskite solution film is obtained, the perovskite solution film is treated in two stages. In the first stage, a vacuum drying treatment is performed, and a ligand atmosphere is formed during the vacuum drying treatment. In the second stage, an annealing treatment is performed.

First, the present invention adopts vacuum drying to obtain the mesophase solid film formed by the complexation of tin-based perovskite and the solvent, so as to reduce the influence of thermal stress on the crystal structure of the thin film in the subsequent annealing process, and employs vacuum-assisted preparation technology to control the uniformity of strain distribution in the perovskite thin film, thereby reducing ion migration in the thin film, and facilitating the realization of efficient and stable manufacturing of tin-based perovskite solar cells. Meanwhile, by reducing the ambient pressure and accelerating the evaporation of the solvent at room temperature, the solution quickly has a high supersaturation, so that a large amount of solute can quickly nucleate on the substrate and growth is facilitated in subsequent annealing, thereby preparing a dense, high-quality perovskite thin film, which can effectively inhibit the leakage current caused by pinholes on the surface of the perovskite thin film and improve the power conversion efficiency of the device.

Second, in the present invention, the ligand atmosphere is formed during the vacuum drying treatment so as to attenuate the defects by means of the ligand, and then annealing is gradually performed to obtain a high-quality tin-based perovskite thin film. By grasping the timing of the defect treatment, the solvent is preliminarily evaporated in the vacuum, and the perovskite in the perovskite solution film is complexed with the solvent to form a mesophase solid film. At this time, uncoordinated tin ion exists on the surface of the mesophase solid film, resulting in the occurrence of dangling bonds and defects. In the present invention, by forming a ligand atmosphere, the volatilized ligand is combined with the uncoordinated tin ion in the mesophase solid film, thereby reducing the dangling bonds and defects on the perovskite surface, and accordingly inhibiting the recombination of charge carriers. Then, the intermediate solid phase film is subjected to annealing treatment. Since the defects of the intermediate solid phase film have been attenuated before annealing, the lattice distortion caused during annealing is reduced, and the quality of the finally obtained perovskite-based tin film is relatively high.

### BRIEF DESCRIPTION OF THE DRAWINGS

FIG. 1 is a flowchart of steps of a method for preparing a tin-based perovskite thin film employing stress control according to an embodiment;

FIG. 2 is an SEM morphology image of a tin-based perovskite thin film provided in Comparative Example 1;

FIG. 3 is an SEM morphology image of a tin-based perovskite thin film provided in Example 1;

FIG. 4 is a comparison graph of performance tests of perovskite solar cells formed by perovskite thin films without ligand treatment and with ligand treatment, respectively;

FIG. 5 is a comparison graph of performance tests of perovskite solar cells formed by perovskite thin films, which are respectively subjected to a ligand treatment directly after annealing and subjected to a ligand treatment during vacuum; and

FIG. 6 is a comparison graph of performance tests of perovskite solar cells formed by perovskite thin films, which are respectively subjected to direct high-temperature annealing and subjected to pre-annealing and then high-temperature annealing, according to an embodiment.

### DETAILED DESCRIPTION

In order for the purpose, technical solution, and advantages of the present invention to be clearer, the present invention is described in further detail below with reference to the accompanying drawings and embodiments. It should be appreciated that the specific embodiments described here are used merely to explain the present invention and are not used to define the present invention. In addition, the technical features involved in various embodiments of the present invention described below can be combined with one another as long as they do not constitute a conflict therebetween.

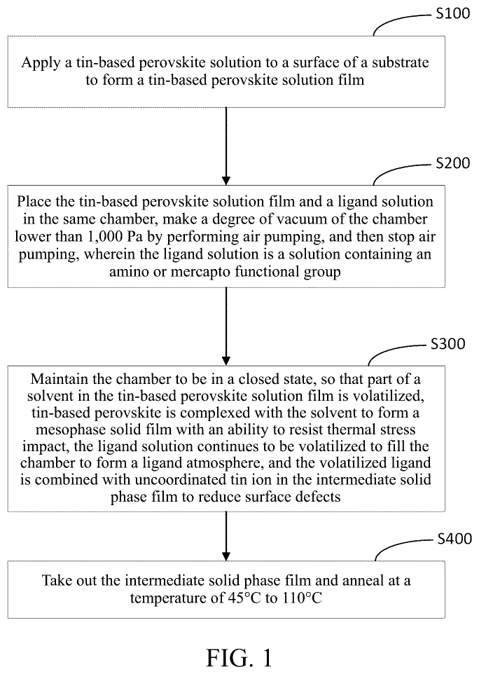

FIG. 1 is a flowchart of steps of a method for preparing a tin-based perovskite thin film employing stress control according to an embodiment. The method mainly includes the following steps:

Step S100: Apply a tin-based perovskite solution to a surface of a substrate to form a tin-based perovskite solution film.

First, the tin-based perovskite solution needs to be prepared. The tin-based perovskite solution may be prepared in accordance with a conventional manner. Specifically, the material of a solute in the tin-based perovskite solution may consist of one or more of methylamine tin iodide, formamidinium tin iodide, methylamine tin iodide bromide, formamidinium tin iodide bromide, cesium tin iodide, cesium tin iodide bromide, phenethylamine tin iodide, n-butylamine tin iodide, isobutylamine tin iodide or xylylenediamine tin iodide. The solvent of the tin-based perovskite solution may be formed by selecting and mixing any one or more of dimethylformamide, dimethylsulfoxide, N,N-dimethylacetamide, y-butyrolactone, and N-methylpyrrolidone. The solute and the solvent are mixed according to a certain ratio to obtain a desired tin-based perovskite solution.

Second, the tin-based perovskite solution is applied to the surface of the substrate to form a tin-based perovskite solution film. Specifically, the solution may be applied by using any process of spin coating, spray coating, soaking, knife coating or roll coating.

Step S200: Place the tin-based perovskite solution film and a ligand solution in the same chamber, make a degree of vacuum of the chamber lower than 1,000 Pa by performing air pumping, and then stop air pumping, wherein the ligand solution is a solution containing an amino or mercapto functional group.

Specifically, the degree of vacuum may be selected from 100 Pa to 1,000 Pa, and the solvent in the tin-based perovskite solution film and the ligand solution may evaporate rapidly in the vacuum. The time of evacuation is as short as possible, so that the solution can quickly reach a supersaturated state, reducing lattice defects. Specifically, the time of evacuation is controlled within 10 s.

The ligand solution may be a solution containing an amino or mercapto functional group, such that the ligand solution can be combined with uncoordinated tin in subsequent steps. Specifically, as the ligand solution may be a mixture of any one or more of methylamine, dimethylamine, ethylamine, diethylamine, ethylenediamine, dipropylamine, 2-phenylethanethiol, ethanethiol, and ethane-1,2-dithiolphenol.

Step S300: Maintain the chamber to be in a closed state, so that part of the solvent in the tin-based perovskite solution film is volatilized, tin-based perovskite is complexed with the solvent to form a mesophase solid film with an ability to resist thermal stress impact, the ligand solution continues to be volatilized to fill the chamber to form a ligand atmosphere, and the volatilized ligand is combined with uncoordinated tin in the mesophase solid film to reduce surface defects.

After air pumping is stopped, the chamber is sealed for a period of time to allow internal reagents to react. Under vacuum, the solvent in the tin-based perovskite solution film and a ligand solvent quickly reach a supersaturated state and are volatilized. Part of the solvent in the tin-based perovskite solution film is volatilized, and tin-based perovskite is complexed with the remaining solvent to form a mesophase solid film. The mesophase is a metal salt and a complex SnX₂·Y, where X is a halogen and Y is a complexing solvent, such as DMSO. After tin-based perovskite is complexed with the remaining solvent to form the mesophase solid film, uncoordinated tin ion exists on the surface of the mesophase solid film, resulting in the occurrence of dangling bonds and defects. At this time, the volatilized ligand is combined with the uncoordinated tin ion to reduce the dangling bonds and defects on the perovskite surface, thereby inhibiting the recombination of charge carriers.

In an embodiment, by controlling the amount of the ligand solution and the duration of the reaction, the extent of reaction of the ligand and the mesophase solid film is controlled. If the reaction between the ligand and the mesophase solid film is too intense, the structure of the intermediate solid phase film will be destroyed, and if the reaction between the ligand and the mesophase solid film is too weak, the effect of reducing the dangling bonds and defects will not be achieved. Therefore, in this embodiment, the volume of the ligand solution is 10 μL to 50 μL, and when the degree of vacuum is 100 Pa to 1,000 Pa, a duration of maintaining the chamber in the closed state is 60 s to 180 s. The effect is better in this parameter range.

Step S400: Take out the mesophase solid film and anneal at a temperature of 45° C. to 110° C.

The mesophase solid film after the defect treatment is then subjected to annealing treatment. Since the mesophase solid film with the ability to resist thermal stress impact has been formed in the vacuum chamber and has been subjected to the defect treatment, the distortion can be reduced during annealing, so that the quality of the finally obtained thin film is relatively high. In an embodiment, low-temperature annealing at 45° C. to 50° C. may be performed first, and then high-temperature annealing at 90° C. to 110° C. may be performed. Since direct high-temperature annealing leads to a direct and rapid phase transition of the tin-based perovskite mesophase solid film, the thin film has many pinholes and is severely affected by thermal stress, which leads to the formation of defects and non-radiative recombination centers again. In contrast, the low-temperature pre-annealing treatment promotes the further fusion and growth of small mesophase grains to form smooth and complete grains. In an embodiment, the duration of low-temperature annealing is controlled to be 3 min to 5 min, and the duration of high-temperature annealing is controlled to be 5 min to 15 min. The control of the annealing duration can not only ensure the fusion and growth of the small mesophase grains, but also ensure the smooth transition of the mesophase into the perovskite structure and removal of the residual solvent.

Correspondingly, the present invention further relates to a high-quality tin-based perovskite thin film prepared by the above preparation method and a photoelectric device including the high-quality tin-based perovskite thin film. The photoelectric device may specifically be a solar cell, a light-emitting diode, a sensor, a transistor or a laser.

Hereinafter, the effects of the present invention will be described with specific comparative examples and examples.

### Comparative Example 1

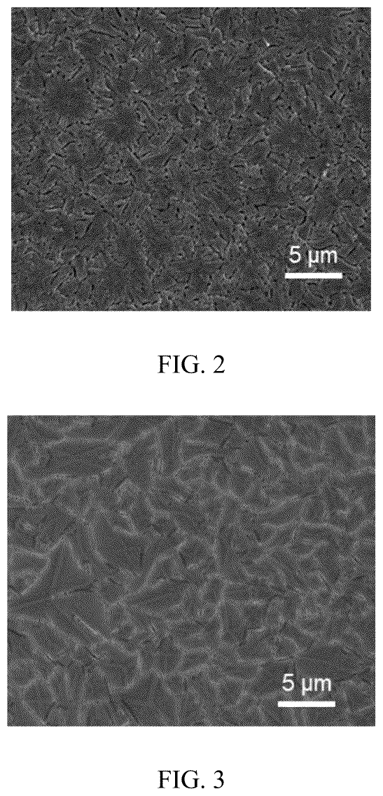

A mixed solvent with a composition of DMF:DMSO=1:0.25 is used to prepare a perovskite precursor solution with a solute composition of CsSnI₃, and a tin-based perovskite thin film is prepared by using a spin coating process and annealing directly at 90° C. for 10 minutes. An SEM image of the surface of the obtained thin film is shown in FIG. 2. It can be seen that the surface of the thin film has holes and incomplete coverage. The open circuit voltage of a device prepared by the obtained tin-based perovskite thin film is 0.31 V, and the power conversion efficiency is 3.75%.

### Comparative Example 2

A mixed solvent with a composition of DMF:DMSO=1:0.25 is used to prepare a perovskite precursor solution with a solute composition of CsSnI₂Br, and a tin-based perovskite thin film is prepared by using a spin coating process and annealing directly at 90° C. for 10 minutes. The open circuit voltage of a device prepared by the obtained tin-based perovskite thin film is 0.32 V, and the power conversion efficiency is 3.88%.

### Comparative Example 3

A mixed solvent with a composition of DMF:DMSO=1:0.25 is used to prepare a perovskite precursor solution with a solute composition of CsSnI₃, and a light yellow perovskite solution film is obtained by using a spin coating process.

The tin-based perovskite solution film is placed in a vacuum chamber, and the chamber is quickly evacuated to reach 1,000 Pa within 5 s, and then maintained in the 1,000 Pa vacuum state for 90 s to obtain a mesophase solid film.

After the mesophase solid film is taken out, the mesophase solid film is directly placed on a hot plate at 90° C. to undergo heat treatment for 10 min. The open circuit voltage of a device prepared by the obtained tin-based perovskite thin film is 0.34 V, and the power conversion efficiency is 4.36%.

### Comparative Example 4

A mixed solvent with a composition of DMF:DMSO=1:0.25 is used to prepare a perovskite precursor solution with a solute composition of CsSnI₃, and after the perovskite precursor solution is subjected to a spin coating process and annealed directly at 90° C. for 10 minutes, a defect passivation treatment is performed in an ethylene diamine ligand atmosphere. The open circuit voltage of a device prepared by the obtained tin-based perovskite thin film is 0.33 V, and the power conversion efficiency is 3.93%.

### Example 1

A mixed solvent with a composition of DMF:DMSO=1:0.25 is used to prepare a perovskite precursor solution with a solute composition of CsSnI₃, and a light yellow perovskite solution film is obtained by using a spin coating process.

The tin-based perovskite solution film and an ethylene diamine solution are placed in a vacuum chamber together, and the chamber is quickly evacuated to reach 1,000 Pa within 5 s, and then maintained in the 1,000 Pa vacuum state for 90 s for a ligand surface treatment to obtain a mesophase solid film.

After the mesophase solid film is taken out, the mesophase solid film is directly placed on a hot plate at 90° C. to undergo heat treatment for 10 min. An SEM image of the surface of the obtained thin film is shown in FIG. 3. The open circuit voltage of a device prepared by the obtained tin-based perovskite thin film is 0.41 V, and the power conversion efficiency is 5.69%.

### Example 2

The difference from the preparation method in Example 1 is that:

the composition of the prepared solute is CsSnI2Br.

### Example 3

The difference from the preparation method in Example 1 is that:

After the mesophase solid film is taken out, the mesophase solid film is first pre-annealed at 45° C. for 5 min, and then annealed at 90° C. for 10 min. The open circuit voltage of a device prepared by the obtained tin-based perovskite thin film is 0.45 V, and the power conversion efficiency is 5.95%.

Comparative data of the comparative examples and examples above are shown in Table 1 below.

TABLE 1
Comparison of data of comparative examples and examples

| | | | | Low- | High- | Open | Power |
|---|---|---|---|---|---|---|---|
| | Perovskite | | Vacuum | temperature | temperature | circuit | conversion |
| | material | Ligand | drying | annealing | annealing | voltage | efficiency |
| Comparative | CsSnI₃ | / | / | / | 90° C. | 0.31 V | 3.75% |
| Example 1 | | | | | | | |
| Comparative | CsSnI₂Br | / | / | / | 90° C. | 0.32 V | 3.88% |
| Example 2 | | | | | | | |
| Comparative | CsSnI₃ | / | 1000 Pa | / | 90° C. | 0.34 V | 4.36% |
| Example 3 | | | | | | | |
| Comparative | CsSnI₃ | Ethylenediamine | / | / | 90° C. | 0.33 V | 3.93% |
| Example 4 | | | | | | | |
| Example 1 | CsSnI₃ | Ethylenediamine | 1000 Pa | / | 90° C. | 0.41 V | 5.69% |
| Example 2 | CsSnI₂Br | Ethylenediamine | 1000 Pa | | 90° C. | 0.42 V | 5.77% |
| Example 3 | CsSnI₃ | Ethylenediamine | 1000 Pa | 45° C. | 90° C. | 0.45 V | 5.95% |

First of all, it can be seen from the comparison of FIGS. 2 and 3 that the surface of the CsSnI₃ thin film obtained by annealing directly has holes and incomplete coverage, whereas the thin film prepared by the present invention is uniform and dense, and has a high coverage rate with respect to the substrate, and it can be observed at a high magnification that the surface of the perovskite thin film has no holes and covers the substrate.

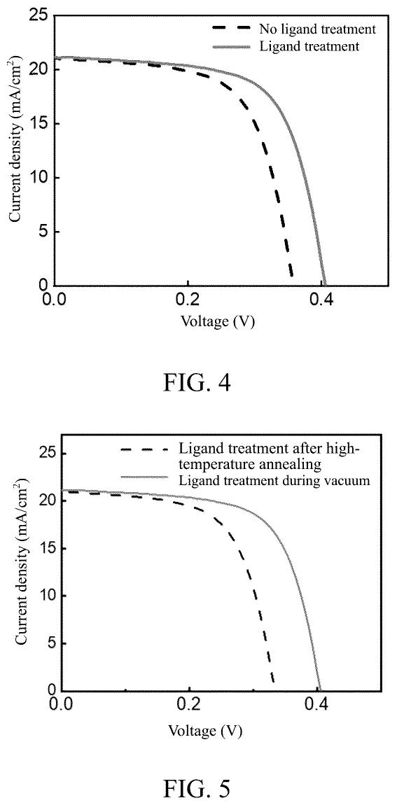

Also, it can be seen from the comparison of Comparative Example 1, Comparative Example 3 and Example 1, the process of vacuum drying+annealing can improve the open circuit voltage compared with the direct high-temperature annealing. With reference to a current-voltage graph shown in FIG. 4, in which the dotted line is a current-voltage curve of a device obtained when a ligand atmosphere is not formed in the vacuum chamber, and the solid line is a current-voltage curve of a device obtained when a ligand atmosphere is formed in the vacuum chamber. It can be seen from the comparison that the photoelectric performance of the obtained device of the present invention is further improved after the ligand atmosphere is formed during vacuum drying.

By comparing Comparative Example 4 and Example 1, with reference to a current-voltage graph shown in FIG. 5, in which the dotted line is a current-voltage curve of a device obtained by performing a ligand treatment after direct annealing, and the solid line is a current-voltage curve of a device obtained when a ligand atmosphere is formed in the vacuum chamber, it can be seen from the comparison that even if the defect treatment is performed in the ligand atmosphere after annealing, the improvement in the performance of the thin film is not obvious, but in the present invention, after the ligand atmosphere is formed during vacuum drying, the photoelectric performance of the obtained device is significantly improved.

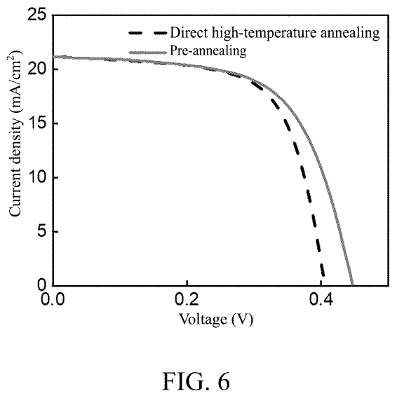

By comparing Examples 1 and 3, with reference to a current-voltage graph shown in FIG. 6, in which the dotted line is a current-voltage curve of a device formed by direct high-temperature annealing after vacuum drying, and the solid line is a current-voltage curve of a device formed by pre-annealing and then high-temperature annealing after vacuum drying, it can be seen from the comparison that performing the low-temperature pre-annealing before the high-temperature annealing during annealing can further improve the performance of the device.

It can be easily understood by a person skilled in the art that the foregoing description is only preferred embodiments of the present invention and is not intended to limit the present invention. Any modifications, equivalent replacements, improvements and so on that are within the spirit and principle of the present invention should be included in the scope of protection of the present invention.

1. A method for preparing a tin-based perovskite thin film employing stress control, the method comprising:
applying a tin-based perovskite solution to a surface of a substrate to form a tin-based perovskite solution film;
placing the tin-based perovskite solution film and a ligand solution in the same chamber, making a degree of vacuum of the chamber lower than 1,000 Pa by performing air pumping, and then stopping air pumping, wherein the ligand solution is a solution containing an amino or mercapto functional group;
maintaining the chamber to be in a closed state, so that part of a solvent in the tin-based perovskite solution film is volatilized, tin-based perovskite is complexed with the solvent to form a mesophase solid film with an ability to resist thermal stress impact, the ligand solution continues to be volatilized to fill the chamber to form a ligand atmosphere, and the volatilized ligand is combined with the uncoordinated tin in the intermediate solid phase film to reduce surface defects; and
taking out the intermediate solid phase film and annealing at a temperature of 45° C. to 110° C.

2. The method for preparing a tin-based perovskite thin film employing stress control according to claim 1, wherein the volume of the ligand solution is 10 μL to 50 μL, the degree of vacuum is 100 Pa to 1,000 Pa, and a duration of maintaining the chamber in the closed state is 60 s to 180 s.

3. The method for preparing a tin-based perovskite thin film employing stress control according to claim 1, wherein a duration of performing air pumping to make the degree of vacuum of the chamber lower than 1,000 Pa is not more than 10 s.

4. The method for preparing a tin-based perovskite thin film employing stress control according to claim 1, wherein a duration of low-temperature annealing is 3 min to 5 min, and a duration of high-temperature annealing is 5 min to 15 min.

5. The method for preparing a tin-based perovskite thin film employing stress control according to claim 1, wherein during annealing, low-temperature annealing at 45° C. to 50° C. is performed first, and then high-temperature annealing at 90° C. to 110° C. is performed.

6. The method for preparing a tin-based perovskite thin film employing stress control according to claim 1, wherein the ligand solution is a mixture of any one or more of methylamine, dimethylamine, ethylamine, diethylamine, ethylenediamine, dipropylamine, 2-phenylethanethiol, ethanethiol, and ethane-1,2-dithiolphenol.

7. The method for preparing a tin-based perovskite thin film employing stress control according to claim 1, wherein the solvent in the tin-based perovskite solution is formed by mixing any one or more of dimethylformamide, dimethylsulfoxide, N,N-dimethylacetamide, γ-butyrolactone, and N-methylpyrrolidone.

8. The method for preparing a tin-based perovskite thin film employing stress control according to claim 1, wherein a solute in the tin-based perovskite solution consists of one or more of methylamine tin iodide, formamidinium tin iodide, methylamine tin iodide bromide, formamidinium tin iodide bromide, cesium tin iodide, cesium tin iodide bromide, phenethylamine tin iodide, n-butylamine tin iodide, isobutylamine tin iodide or xylylenediamine tin iodide.

9. A tin-based perovskite thin film, being prepared by the method for preparing a tin-based perovskite thin film employing stress control according to claim 1.

10. A photoelectric device, comprising the tin-based perovskite thin film according to claim 9.
